(19) United States
(12) Patent Application Publication
(10) Pub. No.: US 2008/0285332 A1
(43) Pub. Date: Nov. 20, 2008

(54) Bit-Alterable, Non-Volatile Memory Management

(76) Inventors: Cheng Zheng, Shanghai (CN); Hongyu Wang, Shanghai (CN)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 10/581,754

(22) PCT Filed: Dec. 30, 2005
(86) PCT No.: PCT/CN05/02385

§ 371 Date: Jun. 5, 2006

(51) Int. Cl. G11C 11/00; G11C 8/00

(52) U.S. Cl. 365/163; 365/230.03; 365/148; 365/230.01

(57) ABSTRACT

Methods and apparatuses for storage of data in bit-alterable, non-volatile memories. In some embodiments, an array of memory locations implemented as bit-alterable, non-volatile memory configured as a plurality of blocks of memory locations; and control circuitry coupled with the array of memory locations to cause a block of data to be stored in the array of memory spanning a boundary between a first block of memory locations and a second block of memory locations. One or more processors access system data during initialization of an electronic system by retrieving data from a pre-selected location in a bit-alterable, non-volatile memory without scanning multiple memory locations to locate the system data.

### TECHNICAL FIELD

Embodiments of the invention relate to use of bit-alterable, non-volatile memory devices. More specifically, embodiments of the invention relate to memory management techniques for use with bit-alterable, non-volatile memory devices.

### BACKGROUND

Many current non-volatile memories, for example, flash memory require data to be organized in blocks that may store file fragments. As a result, significant portions of a block of memory may go unused because of a relationship between the size of the file fragment and the size of the block.

A further characteristic of flash memory is that a complete block of memory must be erased at the same time. Data to be saved beyond the erase operation must be copied to a different block of memory. Thus, erasing data or consolidation of data in flash memory can be a complex and time consuming operation.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a block diagram of one embodiment of an electronic system.

FIG. 2a is a conceptual illustration of a data volume of a traditional, non-volatile memory having system data stored therein.

FIG. 2b is a conceptual illustration of a data volume of a bit-alterable, non-volatile memory having system data stored therein.

FIG. 3 is a flow diagram of one embodiment for utilizing system data in a bit-alterable, non-volatile memory.

FIG. 4a is a conceptual illustration of a traditional non-volatile memory having multiple blocks and storing multiple fragments.

FIG. 4b is a conceptual illustration of a bit-alterable, non-volatile memory having multiple blocks and storing multiple fragments.

FIG. 5a is a conceptual illustration of a traditional non-volatile memory having multiple blocks and storing multiple fragments that correspond to a single file having a size greater than a single block.

FIG. 5b is a conceptual illustration of a bit-alterable, non-volatile memory having multiple blocks and storing multiple fragments that correspond to a single file having a size greater than a single block.

### DETAILED DESCRIPTION

In the following description, numerous specific details are set forth. However, embodiments of the invention may be practiced without these specific details. In other instances, well-known circuits, structures and techniques have not been shown in detail in order not to obscure the understanding of this description.

There currently exist technologies that provide bit-alterable, non-volatile memories. These memories are non-volatile like current flash memories, but unlike current flash memories, individual bit value can be modified without the need to erase an entire block of memory. Thus, bit-alterable, non-volatile memories are potentially more flexible than current flash memories. However, much software has been written in support of flash memory for many applications, for example, removable memory have been written to support the characteristics of flash memory.

File systems utilize various system control data to manage data volume. In traditional flash memory some system data are stored as floating data objects with a specified type or identifier. Examples of which are the Bad Block Table and Shutdown Info. These system data may be updated and their locations may change after multiple updates. Therefore, the file system may be required to scan the whole data volume to search for and identify the system data during initialization.

In a bit-alterable, non-volatile memory these system data could be stored at specific locations and could be edited directly without changing their locations, so there is no need for the file system search. As the wear-leveling issue is concerned, an address table could be used for those frequently updated system data. The address table itself may be stored at a specific location and can direct the file system to the corresponding control data, by which the wear-leveling could be balanced.

In traditional non-volatile (e.g., flash) memory, block removal refers to a technique that may be used to eliminate the file system dependency on flash blocks. To reclaim dirty space, in current flash designs, the file system reserves an empty block as the spare block. During reclamation, valid data may be copied from a data block to the spare block and the original data block may be erased and so the dirty space is reclaimed. Restricted by this mechanism, a single data fragment should not span multiple blocks in traditional non-volatile memory.

However in a bit-alterable, non-volatile memory, the erase operation as used in flash memory is no longer required to reclaim dirty space and file system may not necessary to be aware of memory blocks. Thus, in one embodiment, the block restriction of data fragment storage can be removed. A header-fragment pair now could span multiple blocks and a single data fragment could span multiple blocks.

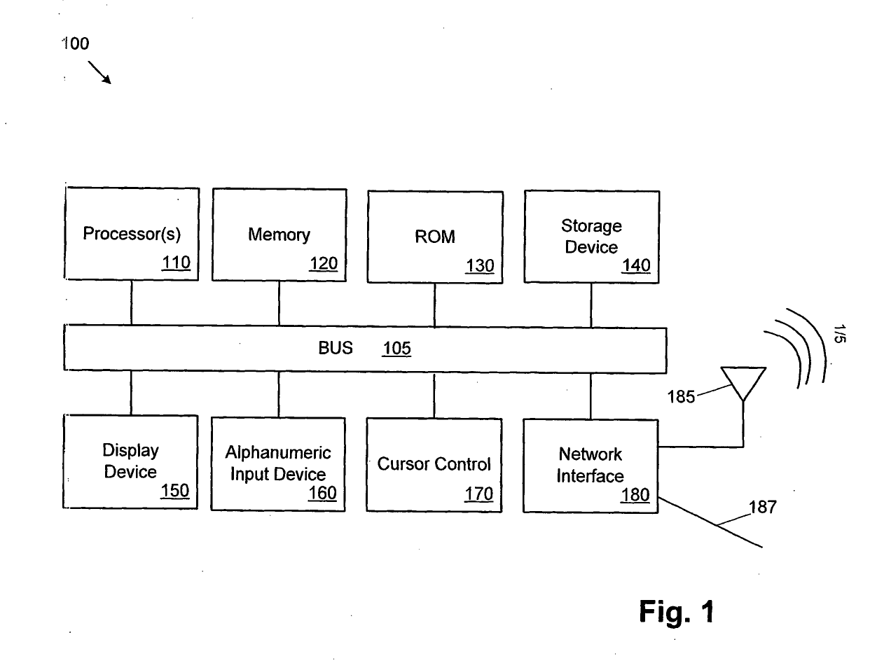

FIG. 1 is a block diagram of one embodiment of an electronic system. The electronic system illustrated in FIG. 1 is intended to represent a range of electronic systems (either wired or wireless) including, for example, desktop computer systems, laptop computer systems, cellular telephones, personal digital assistants (PDAs) including cellular-enabled PDAs, set top boxes. Alternative electronic systems may include more, fewer and/or different components.

Electronic system 100 includes bus 105 or other communication device to communicate information, and processor 110 coupled to bus 105 that may process information. While electronic system 100 is illustrated with a single processor, electronic system 100 may include multiple processors and/or co-processors. Electronic system 100 further may include random access memory (RAM) or other storage device 120 (referred to as memory 120), coupled to bus 105 and may store information and instructions that may be executed by processor 110. Memory 120 may also be used to store temporary variables or other intermediate information during execution of instructions by processor 110. A portion, or all, of memory 120 may include bit-alterable, non-volatile memory.

The bit-alterable, non-volatile memory may include, for example, may be Ovonic Unified Memory™ (OUM™). Ovonic Unified Memory and OUM are trademarks currently owned by Energy Conversion Devices, Inc. Other bit-alterable, non-volatile memory technologies may also exist that may be used as described herein.

UM, for example, is a semiconductor memory technology based on a reversible structural phase change. In a thin film chalcogenide (from Column VI of the Periodic Table) alloy material (e.g., GeSbTe) phase changes between an amorphous phase and a crystalline phase is used as the data storage mechanism. Other phase change alloys may also be used, including, but not limited to, GaSb, InSb, InSe, Sb₂Te₃, GeTe, Ge₂Sb₂Te₅, InSbTe, GaSeTe, SnSb₂Te₄, InSbGe, AgInSbTe, (GeSn)SbTe, GeSb(SeTe), and Te₈₁Ge₁₅Sb₂S₂.

Chalcogenide alloys may exhibit electronic threshold switching that may allow cells to be programmed at a relatively low voltage whether in a resistive or a conductive state. A memory cell may be programmed by application of a current pulse at a voltage above the switching threshold. The programming pulse may drive the memory cell into a high-resistance state or a low-resistance state depending on the current magnitude. Data stored in a cell may be read by measurement of cell resistance.

A relatively small volume of active media in each memory cell acts as a fast programmable resistor that can switch between a high-resistive state and a low-resistive state. In general, OUM may be manufactured using a complementary metal oxide semiconductor (CMOS) process with the addition of layers to form the thin film memory element.

Electronic system 100 may also include read only memory (ROM) and/or other static storage device 130 coupled to bus 105 that may store static information and instructions for processor 110. Data storage device 140 may be coupled to bus 105 to store information and instructions. Data storage device 140 such as a magnetic disk or optical disc and corresponding drive may be coupled to electronic system 100.

Electronic system 100 may also be coupled via bus 105 to display device 150, such as a cathode ray tube (CRT) or liquid crystal display (LCD), to display information to a user. Alphanumeric input device 160, including alphanumeric and other keys, may be coupled to bus 105 to communicate information and command selections to processor 110. Another type of user input device is cursor control 170, such as a mouse, a trackball, or cursor direction keys to communicate direction information and command selections to processor 110 and to control cursor movement on display 150.

Electronic system 100 further may include network interface(s) 180 to provide access to a network, such as a local area network. Network interface(s) 180 may include, for example, a wireless network interface having antenna 185, which may represent one or more antenna(e). Network interface(s) 180 may also include, for example, a wired network interface to communicate with remote devices via network cable 187, which may be, for example, an Ethernet cable, a coaxial cable, a fiber optic cable, a serial cable, or a parallel cable.

In one embodiment, network interface(s) 180 may provide access to a local area network, for example, by conforming to IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Associated as well as previous or subsequent versions of the Bluetooth standard may also be supported.

In addition to, or instead of, communication via wireless LAN standards, network interface(s) 180 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

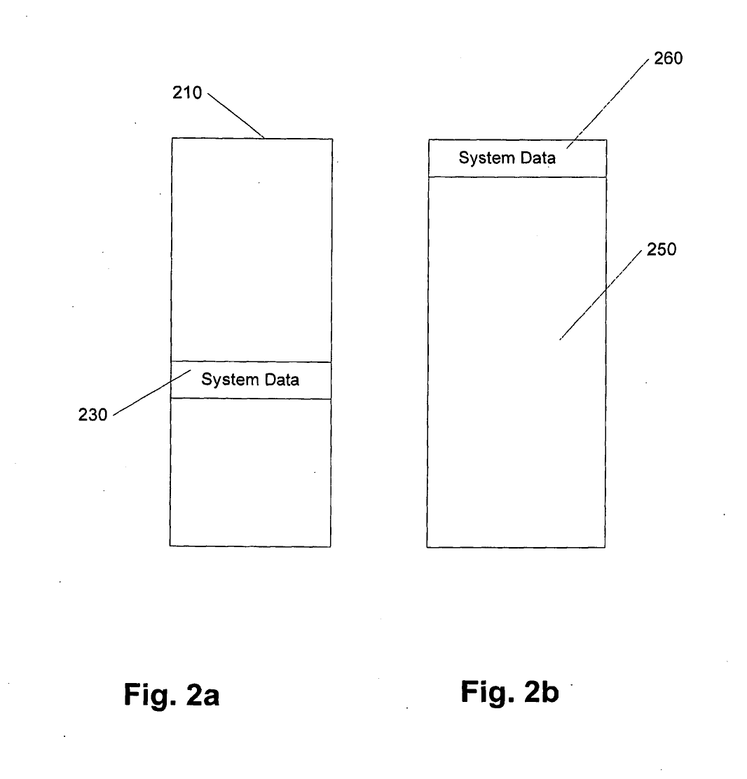

FIG. 2a is a conceptual illustration of a data volume of a traditional, non-volatile memory having system data stored therein. In traditional, non-volatile memories (e.g., flash memory), system data 230 may be stored in any location of data volume 210. In order to locate system data 230, an electronic system with which the memory is used may be required to scan data volume 210 to locate system data 230.

FIG. 2b is a conceptual illustration of a data volume of a bit-alterable, non-volatile memory having system data stored therein. A bit-alterable, non-volatile memory may include data volume 250 that may include system data 260. The system data for the bit-alterable memory may be the same as for the traditional memory except that system data 260 may be stored in a pre-selected location. Therefore, a scan of data volume 250 may not be required to locate system data 260. This may result in a shorter initialization time and therefore a better user experience as compared to traditional non-volatile memory technologies.

If wear leveling is a concern for the bit-alterable, non-volatile memory the memory locations used to store system data 260 may be periodically changed.

In one embodiment, a pointer to system data 260 may be stored in a pre-selected location. Because the expected service life of OUM is much greater than traditional flash memory movement of system data 260 may be unnecessary for some applications.

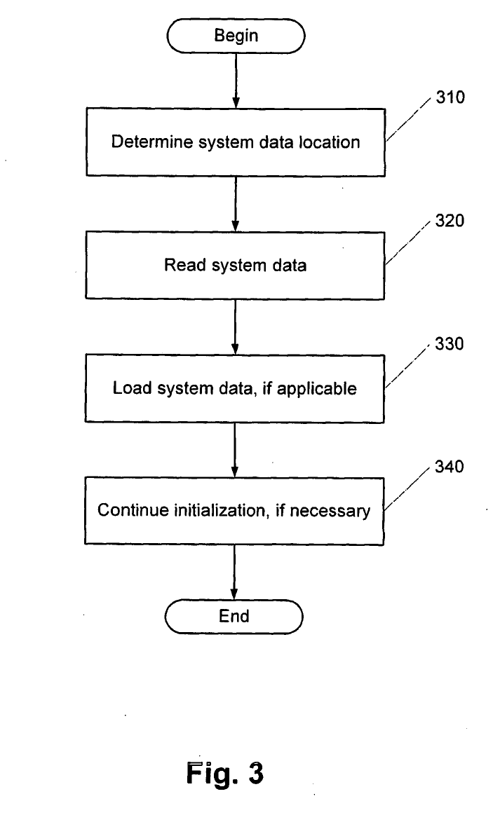

FIG. 3 is a flow diagram of one embodiment for utilizing system data in a bit-alterable, non-volatile memory. A memory location for the system data may be determined, 310. In one embodiment, the system data may be stored beginning at a fixed memory location. Alternatively, the system data may be stored at an offset from the base memory location that as indicated by a stored data value (e.g., an offset value stored in a register or memory location).

The system data may be read or otherwise utilized, 320. That is, the system data may be used in any manner known in the art. The system data may be loaded, if applicable, 330. System initialization may continue using the system data, if necessary, 340.

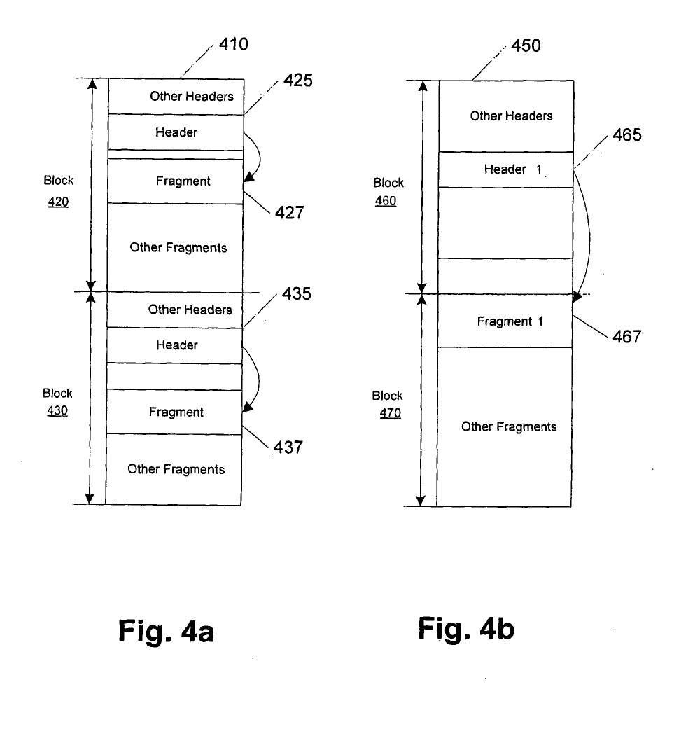

FIG. 4a is a conceptual illustration of a traditional non-volatile memory having multiple blocks and storing multiple fragments. Data volume 410 of the traditional non-volatile memory may include any number of headers including header 425, which includes an indication of the memory location for fragment 427. Fragment 427 must be smaller in size than memory block 420 so as to not overlap the boundary between memory block 420 and memory block 430.

Similarly, data volume 410 of the traditional non-volatile memory may also include header 435, which includes an indication of the memory location for fragment 437. Fragment 437 must be smaller in size than memory block 430 so as to not overlap the boundary between memory block 430 and a subsequent memory block (not illustrated in FIG. 4a). Thus, a utilization of data volume 410 may be inefficient because data may be greatly fragmented, which may require management of many headers as well as access to many memory blocks to access a single file.

FIG. 4b is a conceptual illustration of a bit-alterable, non-volatile memory having multiple blocks and storing multiple fragments. In one embodiment, the bit-alterable, non-volatile memory may utilize the same interface as a traditional non-volatile memory. That is, memory locations may be organized by blocks with a header to store an indication of the memory location of a corresponding data fragment.

In one embodiment, header 465 may be stored starting at a first memory location in data volume 450. Header 465 may include a pointer, or other indication, of a memory location corresponding to fragment 467, which may span a block boundary. That is, fragment 467 may be stored in memory locations that correspond to block 460 and block 470. Other headers and data fragments may be similarly stored in data volume 450.

The data stored in fragment 467 of FIG. 4b may be the same data as stored in fragments 427 and 437 of FIG. 4a. Because data may be stored in fewer fragments for in the bit-alterable, non-volatile memory as compared to the traditional non-volatile memory, fewer headers are required and the available memory locations are used more efficiently. Also, fewer memory accesses may be required, which may result in improved overall system performance.

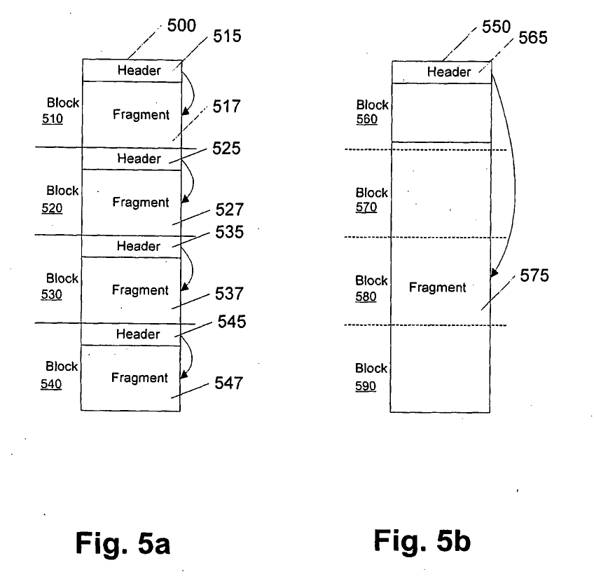

FIG. 5a is a conceptual illustration of a traditional non-volatile memory having multiple blocks and storing multiple fragments that correspond to a single file having a size greater than a single block. Data from a single file, or a single application-level block of data may be split into multiple fragments (e.g., 517, 527, 537, 547) with corresponding headers (e.g., 515, 525, 535, 545). Because the original block of data is larger than any of the individual memory blocks (e.g., 510, 520, 530, 540), a data fragment with corresponding header may completely fill a memory block. Thus, data may be fragmented and overhead added because of the structure of the traditional non-volatile memory. Thus, traditional non-volatile memories may introduce inefficiencies.

FIG. 5b is a conceptual illustration of a bit-alterable, non-volatile memory having multiple blocks and storing multiple fragments that correspond to a single file having a size greater than a single block. The data stored in fragment 575 of data volume 550 in FIG. 5b may be the same data as stored in fragments 517, 527, 537 and 547 of data volume 500 in FIG. 5a. Because a data fragment may cross block boundaries, the single fragment 575 may store the data in logically adjacent memory locations in multiple blocks (e.g., 560, 570, 580, 590) while requiring only a single header (e.g., 565). Because data may be stored in fewer fragments for in the bit-alterable, non-volatile memory as compared to the traditional non-volatile memory, fewer headers are required and the available memory locations are used more efficiently.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

While the invention has been described in terms of several embodiments, those skilled in the art will recognize that the invention is not limited to the embodiments described, but can be practiced with modification and alteration within the spirit and scope of the appended claims. The description is thus to be regarded as illustrative instead of limiting.

What is claimed is:

1. A memory device comprising:
an array of memory locations implemented as bit-alterable, non-volatile memory configured as a plurality of blocks of memory locations; and
control circuitry coupled with the array of memory locations to cause a block of data to be stored in the array of memory spanning a boundary between a first block of memory locations and a second block of memory locations.

2. The memory device of claim 1 wherein the control circuitry causes a header having an indication of a memory location corresponding to the block of data to be stored within the first block of memory locations.

3. The memory device of claim 1 wherein the bit-alterable, non-volatile memory includes cells including a thin film chalcogenide alloy material.

4. The memory device of claim 3 wherein the chalcogenide alloy material comprises GeSbTe.

5. The memory device of claim 3 wherein the chalcogenide alloy material is selected from the group consisting of: GaSb, InSb, InSe, Sb₂Te₃, GeTe, Ge₂Sb₂Te₅, InSbTe, GaSeTe, SnSb₂Te₄, InSbGe, AgInSbTe, (GeSn)SbTe, GeSb(SeTe), and Te₈₁Ge₁₅Sb₂S₂.

6. The memory device of claim 1 wherein the block of data comprises system data to be used during system initialization and further wherein the block of data is stored in a pre-selected location within the memory array for all initialization sequences.

7. A method comprising:
receiving data to be stored in a bit-alterable, non-volatile memory configured as a plurality of blocks of memory locations; and
causing the data to be stored as at least one data fragment that spans a boundary between a first block of memory locations and a second block of memory locations.

8. The method of claim 7 further comprising causing a header having an indication of a memory location corresponding to the data fragment to be stored within the first block of memory locations.

9. The method device of claim 7 wherein the bit-alterable, non-volatile memory includes cells including a thin film chalcogenide alloy material.

10. The method device of claim 9 wherein the chalcogenide alloy material comprises GeSbTe.

11. The method device of claim 9 wherein the chalcogenide alloy material is selected from the group consisting of: GaSb, InSb, InSe, Sb₂Te₃, GeTe, Ge₂Sb₂Te₅, InSbTe, GaSeTe, SnSb₂Te₄, InSbGe, AgInSbTe, (GeSn)SbTe, GeSb(SeTe), and Te₈₁Ge₁₅Sb₂S₂.

12. An article comprising a computer-readable medium having stored thereon instructions that, when executed, cause one or more processors to:
receive data to be stored in a bit-alterable, non-volatile memory configured as a plurality of blocks of memory locations; and
cause the data to be stored as at least one data fragment that spans a boundary between a first block of memory locations and a second block of memory locations.

13. The article of claim 12 further comprising instructions that, when executed, cause the one or more processors to cause a header having an indication of a memory location corresponding to the data fragment to be stored within the first block of memory locations.

14. The article device of claim 12 wherein the bit-alterable, non-volatile memory includes cells including a thin film chalcogenide alloy material.

15. The article device of claim 14 wherein the chalcogenide alloy material comprises GeSbTe.

16. The article device of claim 14 wherein the chalcogenide alloy material is selected from the group consisting of: GaSb, InSb, InSe, Sb₂Te₃, GeTe, Ge₂Sb₂Te₅, InSbTe, GaSeTe, SnSb₂Te₄, InSbGe, AgInSbTe, (GeSn)SbTe, GeSb(SeTe), and Te₈₁Ge₁₅Sb₂S₂.

17. A method comprising accessing system data during initialization of an electronic system by retrieving data from a pre-selected location in a bit-alterable, non-volatile memory without scanning multiple memory locations to locate the system data.

18. The method device of claim 17 wherein the bit-alterable, non-volatile memory includes cells including a thin film chalcogenide alloy material.

19. The method device of claim 18 wherein the chalcogenide alloy material comprises GeSbTe.

20. The method device of claim 18 wherein the chalcogenide alloy material is selected from the group consisting of: GaSb, InSb, InSe, Sb₂Te₃, GeTe, Ge₂Sb₂Te₅, InSbTe, GaSeTe, SnSb₂Te₄, InSbGe, AgInSbTe, (GeSn)SbTe, GeSb(SeTe), and Te₈₁Ge₁₅Sb₂S₂.

21. An article comprising a computer-readable medium having stored thereon instructions that, when executed, cause one or more processors to access system data during initialization of an electronic system by retrieving data from a pre-selected location in a bit-alterable, non-volatile memory without scanning multiple memory locations to locate the system data.

22. The article device of claim 21 wherein the bit-alterable, non-volatile memory includes cells including a thin film chalcogenide alloy material.

23. The article device of claim 22 wherein the chalcogenide alloy material comprises GeSbTe.

24. The article device of claim 22 wherein the chalcogenide alloy material is selected from the group consisting of: GaSb, InSb, InSe, Sb₂Te₃, GeTe, Ge₂Sb₂Te₅, InSbTe, GaSeTe, SnSb₂Te₄, InSbGe, AgInSbTe, (GeSn)SbTe, GeSb(SeTe), and Te₈₁Ge₁₅Sb₂S₂.

25. A system comprising:
an antenna;
a memory system coupled with the antenna, the memory system having an array of memory locations implemented as bit-alterable, non-volatile memory configured as a plurality of blocks of memory locations and control circuitry coupled with the array of memory locations to cause a block of data to be stored in the array of memory spanning a boundary between a first block of memory locations and a second block of memory locations.

26. The system of claim 25 wherein the control circuitry causes a header having an indication of a memory location corresponding to the block of data to be stored within the first block of memory locations.

27. The system of claim 25 wherein the bit-alterable, non-volatile memory includes cells including a thin film chalcogenide alloy material.

28. The system of claim 27 wherein the chalcogenide alloy material comprises GeSbTe.

29. The system of claim 27 wherein the chalcogenide alloy material is selected from the group consisting of: GaSb, InSb, InSe, Sb₂Te₃, GeTe, Ge₂Sb₂Te₅, InSbTe, GaSeTe, SnSb₂Te₄, InSbGe, AgInSbTe, (GeSn)SbTe, GeSb(SeTe), and Te₈₁Ge₁₅Sb₂S₂.
